(19) United States
(12) Patent Application Publication
(10) Pub. No.: US 2016/0116551 A1
(43) Pub. Date: Apr. 28, 2016

(54) MAGNETO-IMPEDANCE SENSOR ELEMENT WITH ELECTROMAGNETIC COIL AND MAGNETO-IMPEDANCE SENSOR WITH ELECTROMAGNETIC COIL

(71) Applicant: MAGNEDESIGN CORPORATION, Aichi (JP)

(72) Inventor: Yoshinobu HONKURA, Chita-gun (JP)

(73) Assignee: MAGNEDESIGN CORPORATION, Chita-gun, Aichi (JP)

(21) Appl. No.: 14/894,227

(22) PCT Filed: Jun. 20, 2014
(86) PCT No.: PCT/JP2014/066447

§ 371 Date: Nov. 25, 2015

(30) Foreign Application Priority Data
Aug. 20, 2013 (JP) 2013-170061

(51) Int. Cl. G01R 33/06

(52) U.S. Cl. CPC G01R 33/063

(57) ABSTRACT

A technique is provided which reduces the coil pitch and increases the number of coil turns in an MI element and allows for high sensitivity and miniaturization. The MI element is configured such that a magnetic wire and a coil wound around the magnetic wire are disposed on an electrode wiring substrate. When manufacturing the coil, a three-layer structure of the coil and thin film coil strips formed by a vapor deposition process are focused on thereby to allow the coil pitch to be 14 micrometers or less. The three-layer structure comprises coil lower portions of a recessed shape, coil upper portions of a protruding shape, and through-hole portions that connect the coil lower portions with the coil upper portions.

### TECHNICAL FIELD

The present invention relates to a technique for reducing the coil pitch and increasing the number of coil turns in a magneto-impedance sensor element (referred to as an “MI element” hereinafter), which uses an electromagnetic coil and is used as a magnetic sensor, thereby to miniaturize the MI element while enhancing the sensitivity or maintaining the sensitivity.

### BACKGROUND ART

Electronic compasses using MI elements are currently used as 3-dimensional compasses for various purposes, such as for smartphones and motion capture. In the future, such electronic compasses are expected as dynamic 3-dimensional compasses and accordingly required to have more enhanced performance. However, while magnetic sensors for electronic compasses using conventional MI-elements have achieved sufficient performance as 3-dimensional compasses, a problem is that enhanced sensitivity and accuracy and miniaturization are insufficient for dynamic 3-dimensional compasses which the market demands. The term “dynamic 3-dimensional compass” as used herein refers to a measuring apparatus that measures the 3-dimensional orientation of a rotating object at an arbitrary time.

MI elements have a structure in which: an amorphous wire as a magnetic sensitive body located at the center portion is fixed to an electrode wiring substrate; an electromagnetic coil is wound around the amorphous wire; and wirings are patterned for four electrodes of wire terminal connection and coil terminal connection. MI elements currently mass-produced have a width of 0.3 mm and a length of 0.6 mm, and the electromagnetic coils of such MI elements have a thickness of about 30 to 50 micrometers (the thickness is defined as the maximum width of lower coils and upper coils), a coil pitch (the sum of coil width and coil separation) of 30 micrometers, a ratio of coil thickness and coil pitch, i.e., a coil aspect ratio defined as coil thickness/coil pitch, of about 1 to 1.7, and the number of coil turns of 17. MI sensors used as electronic compasses utilizing the above MI elements have a sensitivity of about 200 mV/G, a noise level of about 2 mG as the standard deviation, and a measurement range of about ±12 G.

Dynamic 3-dimensional compasses such as used for air mouse and motion capture, however, will require a sensitivity of about 1,000 mV/G, a noise level of about 0.4 mG as the standard deviation, and a measurement range of ±48 G or more. Moreover, for compasses to be built in devices, such as gastroscopes, which are used in living bodies, further miniaturization, preferably a length of 0.3 mm or less, will be demanded. The use in detection of biomagnetism and the like may require a noise level of 0.1 mG or less. To respond to such demands, therefore, the performance of current MI sensors may have to be significantly enhanced.

### CITATION LIST

### Patent Literature

[PTL 1]

U.S. Pat. No. 3,693,119

[PTL 2]

U.S. Pat. No. 4,835,805

### SUMMARY OF INVENTION

### Technical Problem

MI elements put into practical use include those of a type, as disclosed in Patent Literature 1 (FIG. 2 thereof), in which a wire is embedded in a channel and the coil pitch is 60 micrometers when the coil is manufactured using a microfabrication process, and those of a type, as disclosed in Patent Literature 2 (FIG. 2 thereof), in which a wire is attached to a planar substrate using liquid resin and the coil pitch is 30 micrometers. It appears that reducing the coil pitch allows MI sensors to have high sensitivity, low noise, expanded measurement range, and reduced size of micrometer level.

Coils manufactured using the current microfabrication processes include those manufactured using a scheme in which recessed coil components are disposed in a channel of a substrate (Patent Literature 1) and those manufactured using a scheme in which coil components are formed to protrude around a wire (Patent Literature 2). In these schemes, a deep channel or a tall pole for guide are provided in or on a substrate for the purpose of fixation or provisional fixation of the wire, and the channel or pole is used to fix the wire to be aligned on the substrate. According to such methods, however, a large space is generated between a mask and the substrate surface to make it difficult to print fine wirings due to diffraction phenomenon of light at the time of exposure, and the coil pitch is 30 micrometers at best under the present circumstances. Moreover, when the wire is provisionally fixed using liquid resin, the resin permeates a space between the coil and the wire to increase the coil thickness, thus making it difficult to reduce the coil pitch.

Therefore, the conventional methods for forming a coil have limitations that the coil thickness corresponding to a wire diameter of 10 to 15 micrometers is about 30 to 50 micrometers and the coil pitch is 30 micrometers. In other words, it is difficult to achieve a coil pitch of 14 micrometers or less unless the coil aspect ratio is significantly improved from 1.7 to 2 or more.

Furthermore, the thickness of coil strip is about 7 micrometers in order to obtain a small coil resistance, and it is difficult to reduce the coil pitch with such a thickness. To achieve reducing the coil pitch, a thin film coil may have to be manufactured using a vapor deposition process. However, as the cross-sectional area of the coil strip is reduced, the coil resistance increases, so that the output voltage cannot be expected to increase because the coil voltage is affected by a voltage drop due to the coil current.

As described above, problems exist including that the coil aspect ratio should be improved to reduce the coil pitch of a coil to be disposed on the substrate surface, an electronic circuit should be devised which can respond to the increase of the coil resistance due to reduction in the cross-sectional area of the coil strip, and miniaturization of MI sensors will be difficult as long as the element is connected with an integrated circuit by wire bonding even if the element itself can be reduced in size. Another problem is that the output voltage is reduced due to increase of parasitic capacitance.

### Solution to Problem

As a result of intensive studies to solve the above technical problems, the present inventor has conceived of a technical idea of the present invention that the coil aspect ratio can be increased and reduction of the coil pitch can be easily achieved by dividing the coil into three layers and coupling them into a three-element form on a substrate, i.e., a three-layer structure comprising: coil lower portions of a recessed shape; coil upper portions of a protruding shape; and joint portions that joint the coil lower portions and the coil upper portions via a level difference therebetween (or a two-layer structure in a case where the level difference is zero).

The present inventor has also conceived of an idea that the problem of significant increase of the coil resistance due to thinning of the fine-pitch coil strip can be solved by combining the element of the present invention with a sample and hold circuit with a pulse response-type buffer circuit, as substitute for a conventional sample and hold circuit, and connecting the element directly with an integrated circuit using solder without wire bonding connection which would increase the parasitic capacitance.

The present invention will be described hereinafter.

According to a first aspect of the present invention, there is provided a magneto-impedance sensor element with electromagnetic coil, comprising: an electrode wiring substrate; a magnetic sensitive body provided above the electrode wiring substrate; and a coil that is formed to be wound around the magnetic sensitive body. The magneto-impedance sensor element is characterized in that the coil has a multilayer structure in which the coil is divided into three layers comprising: coil lower portions of a recessed shape; coil upper portions of a protruding shape; and joint portions that joint the coil lower portions and the coil upper portions via a level difference therebetween (or two layers in a case where the level difference is zero), and that the coil is isolated from a magnetic wire by an insulating material having an adhesive function while the wire is fixed to the substrate. According to such a structure of three layers, the aspect ratio of a 3-dimensional coil can be tripled to allow the number of coil turns to easily be increased. It is to be noted that the concept of the above joint portions encompasses a case in which the coil lower portions are jointed with the coil upper portions using a through-hole scheme.

When photolithography technique is used to perform patterning of coil wirings on a substrate having irregularities, spaces are generated between the mask and the substrate due to the irregularities, and diffraction phenomenon at the time of exposure limits the strip width. By performing the exposure in a state where half the wire (half the wire cross-section) is embedded in a channel in the substrate while the remaining half is covered with a protruding insulating film, and further by minimizing the thickness of the insulating film, such irregularities can be reduced thereby to reduce the coil pitch.

The present invention may require the wire to be aligned and fixed in a shallow channel. If a liquid resin for provisional fixation is applied, the depth of the channel will be reduced, which may not be preferred. According to the present invention, therefore, one or more magnets may be attached to a table for fixing the substrate, to provisionally fix the wire using the magnetic force, and a resin may then be applied to have a small thickness, so that the resin permeates a space between the channel surface and the wire owing to the power of the surface tension. In this state, a curing process can be performed to fix the wire. Thus, the present invention can take advantages of the magnets and the guiding function of the shallow channel to make the adhesive material thin as much as possible, thereby reducing the coil thickness and the space between the mask and the substrate surface. This allows the coil pitch to be readily reduced.

According to a second aspect of the present invention, which falls under the first aspect of the present invention, there is provided a magneto-impedance sensor element with electromagnetic coil, wherein a magnetic wire covered with an insulating material is employed, wherein the magneto-impedance sensor element is obtained through: embedding only a lower portion of the magnetic wire in a substrate channel provided with wirings of the coil lower portions; fixing the lower portion of the magnetic wire using a resin having an adhesive function and a function as a resist so that an upper portion of the wire is covered by the resin owing to a surface tension of the resin or a part of the upper portion of the wire is exposed; performing an exposure step using the resist applied thereby to perform wiring of the coil upper portions and wiring of the joint portions to form the electromagnetic coil; removing the insulating material from each of the end portions of the wire except the lower portion of the wire embedded in the resin; and thereafter performing wiring between the upper portion of the wire exposed and a wire electrode.

Thus, the present invention may employ a magnetic wire covered with an insulating material thereby to eliminate the problem of insulation between the coil and the wire. When the wire is fixed in the substrate channel formed with wirings of the coil lower portions, the wire may be provisionally fixed in the substrate channel using a table, in which a magnet or magnets are incorporated, for fixing the substrate. In this state, while an adhesive material is not necessary in an area where the upper surfaces of the coil lower portions are in contact with the lowermost surface of the wire, the adhesive material permeates spaces between non-contacting surfaces other than the contacting surfaces to fix the wire. This allows the coil thickness to be reduced as much as possible. The insulating material on each of the end portions of the wire may be removed to expose the metal surface except a part of the insulating material that is present on the lower portion of the wire located in the channel after fixation. The exposed metal surface can be connected with a wire electrode.

According to a third aspect of the present invention, which falls under any of the first and second aspects of the present invention, there is provided a magneto-impedance sensor element with electromagnetic coil, wherein the magnetic sensitive body comprises a conductive and magnetic amorphous wire having a diameter of 1 to 20 micrometers, wherein the coil is a coil that has a coil pitch of 14 micrometers or less, a coil thickness of 30 micrometers or less and 2.5 times or less the wire diameter of the magnetic sensitive body, and a coil aspect ratio of 2 or more, and the magneto-impedance sensor element is configured such that the coil strip has a thickness of 2 micrometers or less, the wire has a length of 0.30 mm or less, and the number of coil turns is 20 or more. The third aspect of the present invention concurrently allows the MI sensor element to be miniaturized and to have high sensitivity.

The coil pitch can thus be reduced by reducing the diameter of the wire and the coil thickness and by employing the thin film coil manufactured through a vapor deposition process and the three-layer structure. Moreover, the coil pitch can readily be reduced by reducing the thickness of the coil strip to 2 micrometers or less. On the other hand, the problem of increase of the coil resistance can be solved by combining the element of the present invention with a sample and hold circuit with buffer circuit.

According to any combination of the above features of the present invention, the length of the wire and MI element can be reduced from the conventional length, i.e., 0.6 mm, to 0.30 mm or less. The measurement range can be significantly improved from ±12 G to ±48 G because the measurement range is in inverse proportion to the wire length. Moreover, even though the wire length is reduced, the number of coil turns can be increased to enhance the sensor sensitivity. In other words, the functionality is achieved to be improved 10 times or more that of the conventional product. In the use for which an ultraminiature sensor is required, such as in living bodies, it is necessary to miniaturize the sensor while maintaining the performance, which can readily be achieved by reducing the coil pitch.

According to a fourth aspect of the present invention, which falls under any of the first and second aspects of the present invention, there is provided a magneto-impedance sensor element with electromagnetic coil, wherein the magnetic sensitive body comprises a conductive and magnetic amorphous wire having a diameter of 1 to 20 micrometers, wherein the coil is a coil that has a coil pitch of 7 micrometers or less, a coil thickness of 25 micrometers or less and 2 times or less the wire diameter of the magnetic sensitive body, and a coil aspect ratio of 5 or more, and the magneto-impedance sensor element is configured such that the coil strip has a thickness of 2 micrometers or less, the wire has a length of 1.00 mm or more, and the number of coil turns is 200 or more.

When detecting an extremely small magnetic field of picotesla level, such as biomagnetism, the number of coil turns may have to be 200 or more. Such a number of coil turns can be achieved by further reducing the coil pitch to 7 micrometers or less and increasing the length of the element (wire length) to 1 mm or more.

According to a fifth aspect of the present invention, which falls under any of the first to fourth aspects of the present invention, there is provided a magneto-impedance sensor element with electromagnetic coil, wherein metal surfaces exposed at the end portions of the magnetic wire are connected to electrodes for the wire via metal vapor-deposited layers, solder balls are attached onto the electrodes for the wire, and the solder balls are used to connect the electrodes for the wire with electrodes on an integrated circuit surface, wherein solder balls are attached onto electrodes for the coil and the solder balls are used to connect the electrodes for the coil with electrodes on the integrated circuit surface.

According to the fifth aspect of the present invention, wire bonding can be omitted, so that the MI sensor is achieved to be miniaturized while reducing the parasitic capacitance of the element and reducing the IR drop (voltage drop) due to increase of the coil-related resistance. This allows the MI sensor to have enhanced sensitivity.

According to a sixth aspect of the present invention, which may fall under any of the first to fifth aspects of the present invention, there is provided a magneto-impedance sensor with electromagnetic coil, wherein a sample and hold circuit detects a voltage output of the electromagnetic coil via a pulse response-type buffer circuit.

In the conventional sample and hold circuit, as the resistance of the MI element increases, even if the number of coil turns is increased, an output voltage proportional thereto cannot be obtained due to the voltage drop caused from the IR drop. It is considered that an ordinary buffer circuit cannot respond to a pulse voltage of GHz for MI sensors because the frequency band is around 1 MHz or the like. Raising the frequency band to GHz may not be practical because the consumption current of the buffer circuit significantly increases. To this problem, the present inventor has found that, when a high impedance circuit consisting only of a buffer circuit and an MI element at the input side is combined with a high impedance circuit comprising an electronic switch, a capacitor (capacitance is about 5 pF) and an amplifier at the output side, the output side becomes low impedance only for a moment of nanoseconds order during which a pulse voltage is generated in the coil, and can function as a buffer circuit such that the same voltage as that in the coil is held in the capacitor. That is, in this configuration, it can be considered as if the frequency band of the buffer circuit is increased to GHz for a moment of nanoseconds. This configuration is referred to as a “pulse response-type buffer circuit.”

According to the sixth aspect of the present invention, the MI element having a fine coil and the pulse response-type buffer circuit are combined thereby to significantly enhance the sensitivity of the MI sensor.

### Effect of Invention

The magneto-impedance sensor element with electromagnetic coil according to the first aspect of the present invention has features that the coil formed to be wound around the magnetic sensitive body above the electrode wiring substrate has a three-layer structure comprising: coil lower portions of a recessed shape; coil upper portions of a protruding shape; and joint portions that joint the coil lower portions and the coil upper portions and that the coil is isolated from the magnetic wire by an insulating material. According to the features, an increased coil aspect ratio and a finely pitched coil can readily be achieved. Consequently, when the element of the present invention is combined with a sample and hold circuit with buffer circuit, or when the direct connection of the MI element with an integrated circuit using solder is further combined therewith, effects are obtained that the MI sensor can have high sensitivity, low noise, and expanded measurement range, and can be miniaturized.

The magneto-impedance sensor element with electromagnetic coil according to the second aspect of the present invention has a feature of employing a magnetic wire covered with an insulating material in addition to the features of the first aspect of the present invention. According to the feature, spaces between the coil lower portions of a recessed shape and the coil upper portions of a protruding shape can be further reduced thereby to further reduce the coil pitch.

The magneto-impedance sensor element with electromagnetic coil according to the third aspect of the present invention has features that the length is 0.30 mm or less and the number of coil turns is 20 or more. The features concurrently allow the MI sensor element to be miniaturized and to have high sensitivity and expanded measurement range.

The magneto-impedance sensor element with electromagnetic coil according to the fourth aspect of the present invention has a feature that the number of coil turns is 200 or more. This feature provides an effect that an extremely small magnetic field of picotesla level, such as biomagnetism, can be detected.

The magneto-impedance sensor element with electromagnetic coil according to the fifth aspect of the present invention has a feature that solder balls are attached onto the electrodes of the magnetic wire and electrodes of the coil, in addition to any of the feature or features of the first to fourth aspects of the present invention. This feature allows direct connection to the surface of an integrated circuit. By eliminating a method of wire bonding connection, effects are obtained that the sensor can be achieved to be miniaturized while reducing the parasitic capacitance of the coil and reducing the voltage drop due to the IR drop in the detected coil voltage which is input to a buffer circuit.

The magneto-impedance sensor with electromagnetic coil according to the sixth aspect of the present invention has a feature that the voltage output from the electromagnetic coil of the element according to any of the first to fifth aspects of the present invention is detected by a sample and hold circuit via the pulse response-type buffer circuit. This feature provides an effect that the current flowing through the coil can be suppressed to minimize the voltage drop, thereby allowing the sensor to have high sensitivity and low noise.

### BRIEF DESCRIPTION OF DRAWINGS

FIG. 1 is a schematic front elevational view of an MI element according to a first embodiment and a first example.

FIG. 2 is a schematic cross-sectional view, along line A1-A2 in FIG. 1, of the MI element according to the first embodiment and the first example.

FIG. 3 is a schematic view of coil lower portions in the first embodiment and the first example.

FIG. 4 is a schematic view of coil upper portions in the first embodiment and the first example.

FIG. 5 is a schematic view of the connection between the upper and lower coils in the cross-section along line B1-B2 in FIG. 2 in the first embodiment and the first example.

FIG. 6 is a schematic cross-sectional view, along line A3-A4 in FIG. 1, of the MI element according to the first embodiment and the first example.

FIG. 7 is a block diagram showing an electronic circuit of an MI sensor in a second embodiment and examples.

FIG. 8 is a graph showing characteristics which represent a relationship between a sensor output voltage and an external magnetic field in the second example and Comparative Examples 1 and 2.

### DESCRIPTION OF EMBODIMENTS

Hereinafter, embodiments of the present invention will be described with reference to the drawings.

### First Embodiment

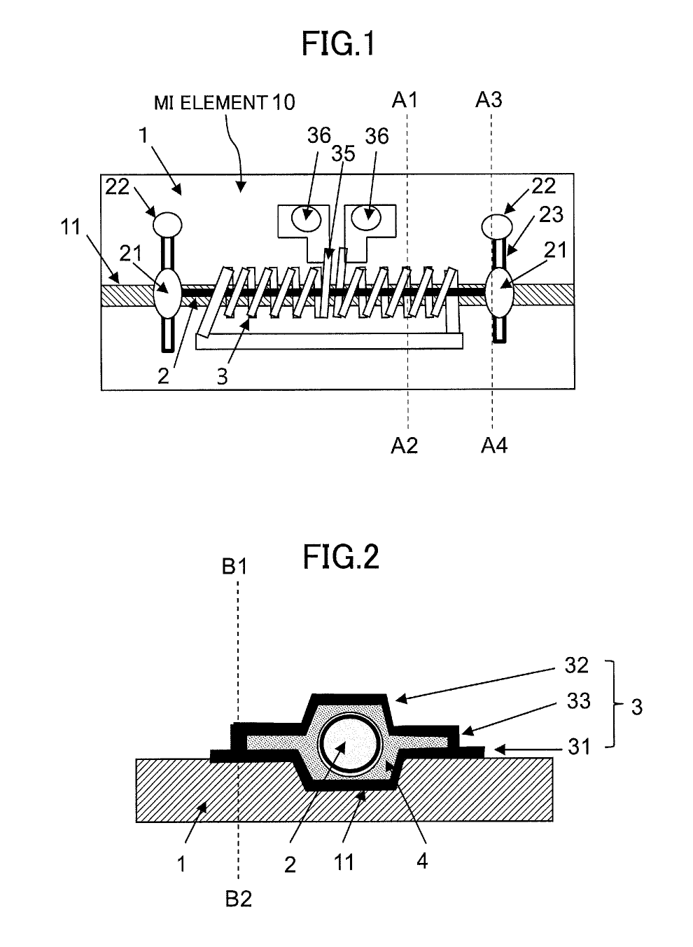

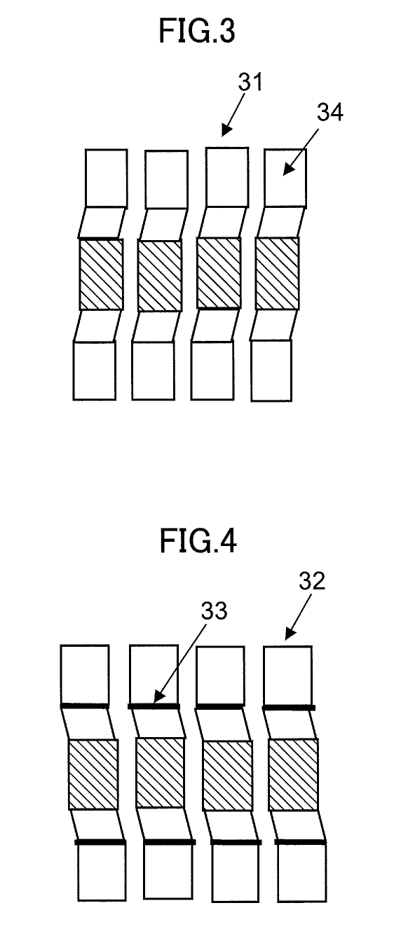

The magneto-impedance sensor element with electromagnetic coil of the first embodiment will be described with reference to an MI element shown in FIG. 1 and FIG. 2. In the MI element, an amorphous magnetic wire 2 of Co alloy for detecting a magnetic field is located above an electrode wiring substrate 1 so that the magnetic wire 2 is supported via an insulator 4 by an electromagnetic coil 3 of a three-layer structure, i.e., an electromagnetic coil 3 that has a structure comprising: coil lower portions 31 of a recessed shape; coil upper portions 32 of a protruding shape; and joint portions 33 that joint the coil lower portions 31 and the coil upper portions 32. The electromagnetic coil 3 has a coil pitch of 14 micrometers or less, an inner diameter of 40 micrometers or less, and a coil aspect ratio of 2 or more. Terminals of the wire 2 and electromagnetic coil 3 are connected to respective electrodes 22 and 36 on the electrode wiring substrate 1, and solder balls are disposed on the electrodes 22 and 36 to be connected to an integrated circuit. When a high-frequency or pulse current is caused to flow through the wire 2, the electromagnetic coil 3 outputs a voltage corresponding to the intensity of an external magnetic field generating around the electromagnetic coil 3. The voltage is detected by the integrated circuit.

In the MI element of the present embodiment, the wire 2 is an amorphous magnetic wire of conductive Co alloy having a diameter of 1 to 20 micrometers. The electrode wiring substrate 1 has a channel 11 of which the depth is about half the wire diameter (15 micrometers or less). The electromagnetic coil 3 has a three-layer structure in which the coil lower portions 31 of the electromagnetic coil 3 are disposed along the channel surface, the coil upper portions 32 of a protruding shape having a height of 25 micrometers or less are disposed on or above the coil lower portions 31, and the joint portions 33 joint the coil lower portions 31 and the coil upper portions 32 via a level difference of 0.5 to 30 micrometers therebetween. This three-layer structure can ensure a coil aspect ratio of 2 or more thereby to allow the coil pitch to be 14 micrometers or less. It should be noted that the present invention can encompass a two-layer structure in a special case where the level difference between the upper and lower coils is zero, substantially as a special case of the three-layer structure.

In the present embodiment, a preferred wire diameter is 6 to 15 micrometers. In this case, the height ratio of the three layers may be the equally divided ratio in principle. In this instance, the channel depth is preferably 2 to 10 micrometers. The height of the protruding portions of the upper coil side is also preferably 2 to 10 micrometers. In this case, the coil thickness can be 10 to 30 micrometers, the coil aspect ratio can be 3 to 5, and the coil pitch can be 2 to 10 micrometers.

According to the present embodiment, the output voltage per one turn of the electromagnetic coil can be increased to allow the sensor to have high sensitivity because the amorphous magnetic wire of Co alloy has excellent performance of magnetic sensitivity.

Moreover, according to the present embodiment, the coil pitch can be reduced even when various wires having difference diameters are used with the same aspect ratio, by setting the coil thickness to 1.005 times to 10 times the wire diameter. Therefore, the present embodiment can provide an element having high sensitivity and low noise.

Furthermore, according to the present embodiment, a coil pitch of 14 micrometers or less can be readily achieved by employing coil strips having a thickness of 2 micrometers or less.

In addition, according to the present embodiment, when the coil pitch is 14 micrometers or less, the number of coil turns comparable with that of the conventional MI element can be ensured even with a length of the above MI element of 0.30 mm or less. Therefore, the present embodiment provides an element that is able to be miniaturized while in a state of maintaining high sensitivity.

According to the present embodiment, when the coil pitch is 14 micrometers or less, if the length of the above MI element is 1 mm or more and the number of coil turns is 200 or more, there is provided an element which can have considerably high sensitivity of a noise level of 0.1 mG or less while being miniaturized.

Moreover, the present embodiment has a feature that solder balls are connected with the wire electrodes and coil electrodes to allow direct connection with an integrated circuit. According to this feature of the present embodiment, miniaturization of MI sensors can be achieved.

### Second Embodiment

The second embodiment relates to an MI sensor in which the MI element of the first embodiment and a sample and hold circuit with buffer circuit are used in combination. In a fine-pitch coil, when the coil separation is reduced to half to double the number of coil turns, the cross-sectional area of the coil strips may have to be half if the coil strip thickness is the same, and the coil length is doubled. This results in the electrical resistance quadrupled. If the coil output voltage is directly sampled and held via an electrical switch, a current flows in the coil to quadruple the voltage drop, which significantly reduce the measurement value of the coil output voltage. Therefore, the present embodiment employs a circuit that samples and holds the output voltage via a buffer circuit and an electrical switch, thereby to provide an MI sensor which can suppress the voltage drop to obtain an output voltage proportional to the number of coil turns.

### EXAMPLE 1

Hereinafter, examples of the present invention will be described with reference to the drawings.

The magneto-impedance sensor element with electromagnetic coil of the first example will now be described with reference to FIG. 1 and FIG. 2.

The electrode wiring substrate 1 has a size of a length of 0.3 mm, a width of 0.2 mm, and a height of 0.2 mm. The magnetic sensitive body is an amorphous wire 2 of CoFeSiB-based alloy having a diameter of 10 micrometers and covered with glass. The coil lower portions 31 of a recessed-shape on the substrate 1 have a depth of 7 micrometers, a strip width of 2 micrometers, a coil width of 40 micrometers, and a thickness of 1 micrometer. The joint portions 33 have a height of 1 micrometer and a thickness of 1 micrometer. The coil upper portions 32 of a protruding shape have a height of 7 micrometers, a strip width of 2 micrometers, a coil width of 40 micrometers, and a thickness of 1 micrometer. The electromagnetic coil 3 has a three-layer structure of a thickness of 14 micrometers. The coil pitch is 5 micrometers, the coil aspect ratio is 2.6, and the number of coil turns is 50.

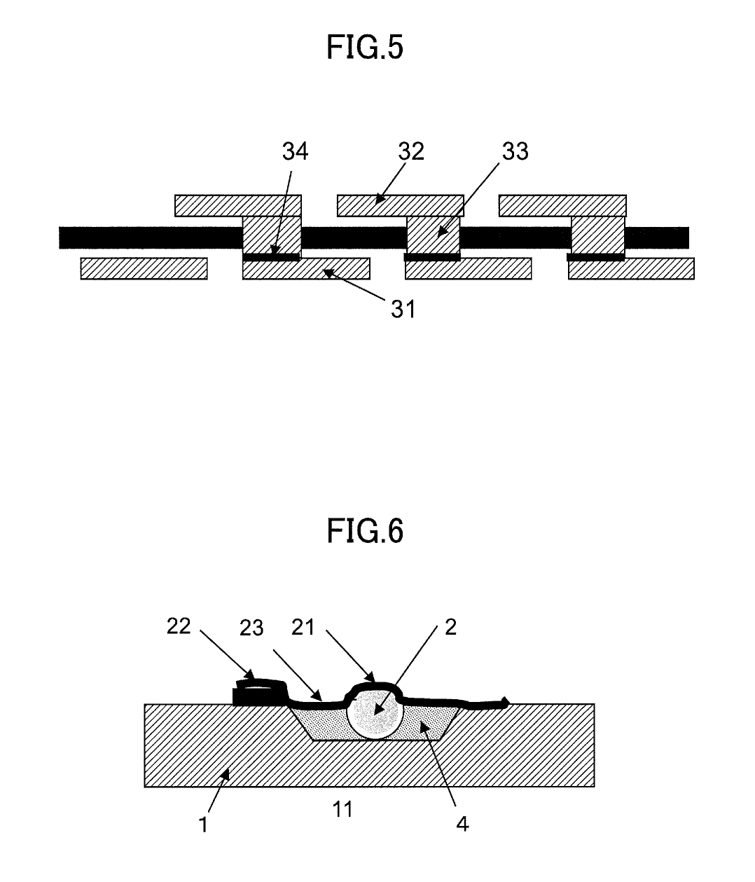

The wiring structure of the three-layer coil will be described with reference to FIG. 3 to FIG. 6. As shown in FIG. 3, the coil lower portions 31 of a recessed shape are formed through: forming a channel 11 in the electrode wiring substrate 1 in the longitudinal direction; forming by vapor deposition a conductive metal thin film (thickness of 1 micrometer), which constitutes the coil lower portions 31, on the whole surface of the channel 11 and on an adjacent area to the channel 11 in the upper surface of the electrode wiring substrate 1; and removing a part of the conductive metal thin film using a selective etching method so that the remaining metal thin films each form a crank-like shape.

After the magnetic wire is placed in the channel patterned with wirings of the coil lower portions 31 of a recessed shape, resin is applied thereto by spin coating to have a thickness of 1 micrometer and cured to form a resin layer 4 which provides the second layer surface. Thereafter, the joint portions 33 of a thickness of 1 micrometer and crank portions 34 of the coil lower portions 31 are electrically connected with one another on the second layer surface.

The coil upper portions 33 of a protruding shape are formed through: applying resin to the resin layer 4 at the second layer surface along the upper portion of the wire to have a protruding shape of a height of 7 micrometers; forming by vapor deposition a conductive metal thin film (thickness of 1 micrometer), which constitutes the coil, on the surface of the protruding resin; and removing a part of the conductive metal thin film using a selective etching method so that the remaining metal thin films each form a crank-like shape. Crank portions of the coil upper portions 32 are electrically connected with the joint portions 33.

The electromagnetic coil 3 is maintained to be insulated from the amorphous wire 2 by the glass which covers the amorphous wire. The amorphous wire 2 is fixed to the substrate using resin. Four electrodes for the conductive amorphous wire 2 and electromagnetic coil are formed on the electrode wiring substrate 1. More specifically, two coil electrodes 36 for the electromagnetic coil 3 and two wire electrodes 22 for the amorphous wire 2 as the magnetic sensitive body are printed on the top surface of the electrode wiring substrate 1.

Each amorphous wire terminal 21 is connected to the metal surface exposed at the end portion of the amorphous wire 2 via a metal vapor-deposited film, and the amorphous wire terminal 21 is also connected to the wire electrode 22 via a metal vapor-deposited film 23. Solder balls are disposed on the wire electrodes 22 and on the coil electrodes 36 which are extended from the coil terminals 35 of the electromagnetic coil 3, and the wire electrodes 22 and the coil electrodes 36 are directly connected with terminals at the side of an integrated circuit by heating the solder balls. This can achieve to miniaturize the sensor. In addition, reduction of electromagnetic noises during pulse oscillation can also be promoted because wire bonding is not used. Moreover, the wire is strongly bonded to the wire terminals of the MI element using solder, and the MI element can thereby have an enhanced mechanical strength.

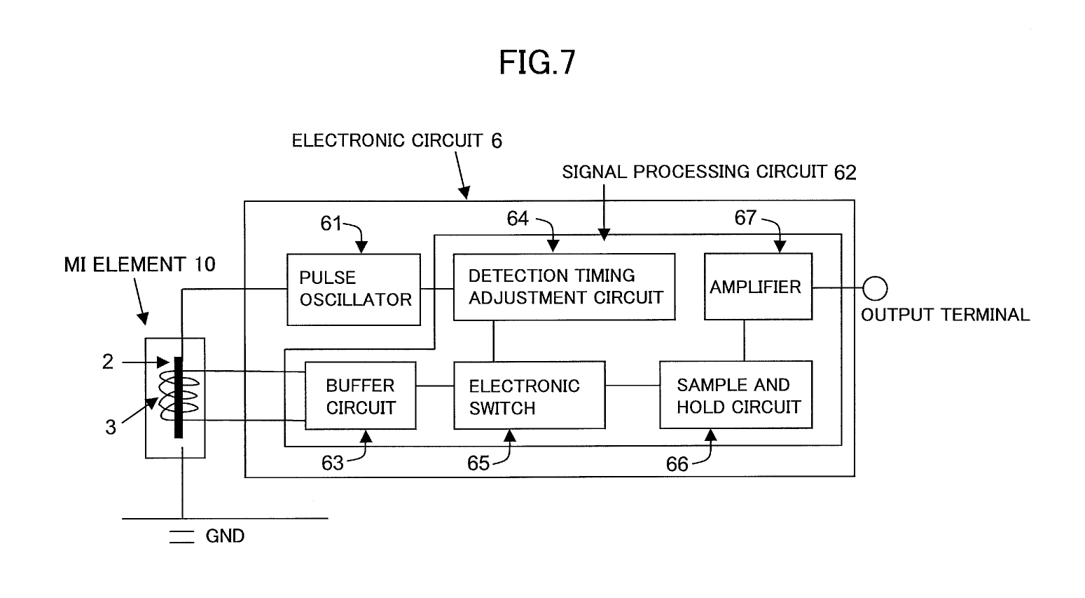

Next, characteristics of the MI element 10 were evaluated using an electronic circuit for MI sensors as shown in FIG. 7.

The electronic circuit comprises a pulse oscillator 61, the MI element 10, and a signal processing circuit 62 that has a buffer circuit 63. The signals used are pulse signals that correspond to 500 MHz and have an intensity of 100 mA, and the signal interval is 1 microsecond. The pulse signals are input to the amorphous wire 2, and a voltage proportional to an external magnetic field is generated in the electromagnetic coil 3 while the pulses are applied.

The signal processing circuit 62 is configured such that the voltage generated in the electromagnetic coil 3 is input to the buffer circuit 63 and the output from the buffer circuit 63 is input to a sample and hold circuit 66 via an electronic switch 65. The timing of on/off of the electronic switch is adjusted by a detection timing adjustment circuit 64 to an appropriate timing for the pulse signals, and the voltage at the timing is sampled and held. The sampled and held voltage is then amplified by an amplifier 67 to a certain voltage.

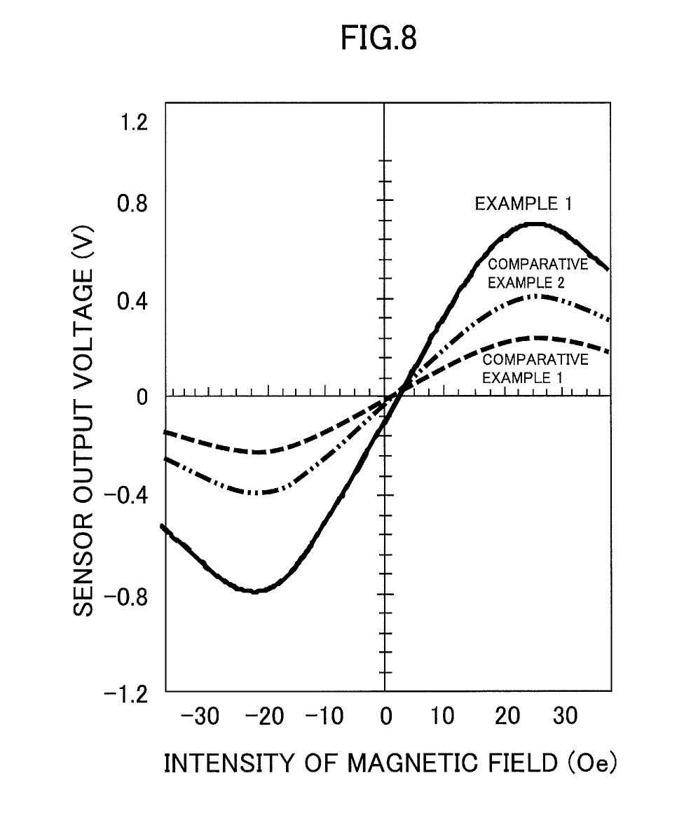

FIG. 8 shows the sensor output from the circuit. Horizontal axis of FIG. 8 represents the magnitude of an external magnetic field while vertical axis represents the output voltage of the sensor. The output of the sensor exhibits good linearity within a range of the magnitude of the magnetic field of ±10 G. The sensitivity was 42 mV/G.

As a comparative example, an MI element used in a commercially available product AMI306 was measured and evaluated using the same electronic circuit. The result is shown in FIG. 8 as Comparative Example 1. The sensitivity was 14 mV/G. The size of the MI element of the comparative example is a size of a width of 0.3 mm, a height of 0.2 mm, and a length of 0.6 mm, i.e., three times the size of the present example. The same amorphous wire as that of the present example is used as the magnetic sensitive body. It can be found from the result that the sensitivity is tripled due to the number of coil turns being tripled, as an effect of enhancing the sensitivity by using the fine-pitch coil of the present example.

The electronic compass manufactured in the first example has achieved high sensitivity and low noise which dynamic 3-dimensional compasses require, and application thereof is expected.

### EXAMPLE 2

The second example is configured such that the magneto-impedance sensor element with electromagnetic coil of Example 1 and a signal processing circuit 62 with buffer circuit are used in combination. The MI element has a coil of which the coil pitch is 5 micrometers, the number of coil turns is 50, the length is 0.3 mm, and the coil resistance is 48 ohm.

The electronic circuit 6 comprises a pulse oscillator 61 and a signal processing circuit 62. The signal processing circuit 62 comprises a buffer circuit 63, a detection timing adjustment circuit 64, an electronic switch 65, a sample and hold circuit 66, and amplifier 67. The pulse oscillator 61 inputs pulse signals, which have an oscillation frequency corresponding to 500 MHz and an intensity of current of 100 mA, to the wire portion of the MI element. The voltage generated in the coil of the MI element is input to the buffer circuit 63. The output voltage from the buffer circuit 63 is held by the sample and hold circuit 66 via the electronic switch 65, and the voltage is then amplified by the amplifier 67. The on/off of the electronic switch 65 is adjusted by the detection timing adjustment circuit 64 so that the electronic switch 65 turns on and off at an appropriate timing synchronized with the pulse signals. The voltage at a time when the electronic switch 65 turns off is sampled and held.

Comparative examples include Comparative Example 1 in which the conventional MI element is combined with a circuit with buffer circuit and Comparative Example 2 in which the MI element of Example 1 of the present invention is combined with a circuit without buffer circuit. Performance of the present example was compared with those of the two comparative examples. Results were as follows: the sensitivity of Comparative Example 1 was 14 mV/G and the sensitivity of Comparative Example 2 was 20 mV/G, whereas the sensitivity of Example 2 was significantly enhanced to 42 mV/G.

The above-described embodiments and examples are exemplified for descriptive purposes and the present invention is not limited thereto. Any modification and addition can be made without departing from the technical idea of the present invention which a person skilled in the art can recognize from the statement in the claims, the detailed explanation of invention, and the drawings.

### INDUSTRIAL APPLICABILITY

As heretofore described, the magneto-impedance sensor element with fine pitch electromagnetic coil of the present invention is considerably miniaturized and has high sensitivity, and can thus be applicable as a dynamic 3-dimensional compass to various fields, such as for smartphones and motion capture.

### REFERENCE SIGNS LIST

1: Substrate of MI element

10: MI element

11: Channel in substrate

2: Amorphous wire

21: Wire terminal

22: Wire electrode

23: Connection portion

24: Wire covered with insulating material

3: Electromagnetic coil

31: Coil lower portion

32: Coil upper portion

33: Joint portion

34: Crank portion

35: Coil terminal

36: Coil electrode

6: Electronic circuit

61: Pulse oscillator

62: Signal processing circuit

63: Buffer circuit

64: Detection timing adjustment circuit

65: Electronic switch

66: Sample and hold circuit

67: Amplifier

1. A magneto-impedance sensor element with electromagnetic coil, comprising:
an electrode wiring substrate;
a magnetic wire that is a magnetic sensitive body and provided above the electrode wiring substrate;
a coil that is wound around the magnetic wire; and
four terminals that are formed on the electrode wiring substrate to connect end portions of the magnetic wire and the coil with an external integrated circuit,
wherein the coil has a three-layer structure comprising: coil lower portions of a recessed shape; coil upper portions of a protruding shape; and joint portions that joint the coil lower portions and the coil upper portions via a level difference therebetween (or a two-layer structure in a special case where the level difference is zero),
wherein the coil is electrically isolated from the magnetic wire by an insulating material having an adhesive function while the wire is fixed to the substrate.

2. The magneto-impedance sensor element with electromagnetic coil as recited in claim 1, wherein the magnetic wire is covered with an insulating material,
wherein the magneto-impedance sensor element is obtained through:
embedding only a lower portion of the magnetic wire in a substrate channel provided with wirings of the coil lower portions;
fixing the lower portion of the magnetic wire using a resin having an adhesive function and a function as a resist so that an upper portion of the wire is covered by the resin owing to a surface tension of the resin or a part of the upper portion of the wire is exposed;
performing an exposure step using the resist applied thereby to perform wiring of the coil upper portions and wiring of the joint portions to form the electromagnetic coil with a small coil thickness;
removing a glass coating from each of the end portions of the wire except the lower portion of the wire embedded in the resin; and
thereafter performing wiring between the upper portion of the wire exposed and a wire electrode.

3. The magneto-impedance sensor element with electromagnetic coil as recited in claim 1, wherein the magnetic sensitive body comprises a conductive and magnetic amorphous wire having a diameter of 1 to 20 micrometers, wherein the coil is a coil that has a coil pitch of 14 micrometers or less, a coil thickness of 30 micrometers or less and 2.5 times or less the wire diameter of the magnetic sensitive body, and a coil aspect ratio of 2 or more, and the magneto-impedance sensor element is configured such that a coil strip has a thickness of 2 micrometers or less, the wire has a length of 0.30 mm or less, and the number of coil turns is 20 or more.

4. The magneto-impedance sensor element with electromagnetic coil as recited in claim 1, wherein the magnetic sensitive body comprises a conductive and magnetic amorphous wire having a diameter of 1 to 20 micrometers, wherein the coil is a coil that has a coil pitch of 7 micrometers or less, a coil thickness of 25 micrometers or less and 2 times or less the wire diameter of the magnetic sensitive body, and a coil aspect ratio of 5 or more, and the magneto-impedance sensor element is configured such that a coil strip has a thickness of 2 micrometers or less, the wire has a length of 1.00 mm or more, and the number of coil turns is 200 or more.

5. The magneto-impedance sensor element with electromagnetic coil as recited in claim 1, wherein metal surfaces exposed at the end portions of the magnetic wire are connected to wire terminals via metal vapor-deposited layers, solder balls are attached onto wire electrodes extended from the wire terminals, and the solder balls are used to connect the wire electrodes with terminals on the integrated circuit surface, wherein solder balls are attached onto coil electrodes extended from coil terminals and the solder balls are used to connect the coil electrodes with terminals on the integrated circuit surface.

6. A magneto-impedance sensor with electromagnetic coil, comprising:
the magneto-impedance sensor element as recited in claim 1; and
an electric circuit that detects a voltage output of the electromagnetic coil by a sample and hold circuit via a pulse response-type buffer circuit.
